(19) United States
(12) Patent Application Publication
(10) Pub. No.: US 2011/0032687 A1
(43) Pub. Date: Feb. 10, 2011

(54) PLASMA DISPLAY DEVICE

(75) Inventor: Keun-Young SONG, Yongin-si (KR)

Correspondence Address: KNOBBE MARTENS OLSON & BEAR LLP, 2040 MAIN STREET, FOURTEENTH FLOOR, IRVINE, CA, 92614, US

(73) Assignee: Samsung SDI Co., Ltd., Yongin-si (KR)

(21) Appl. No.: 12/821,957

(22) Filed: Jun. 23, 2010

(30) Foreign Application Priority Data
Aug. 4, 2009 (KR) 10-2009-0071785

(51) Int. Cl. H05K 1/11

(52) U.S. Cl. 361/803

(57) ABSTRACT

A plasma display device is disclosed. In one embodiment, the device includes 1) a plasma display panel (PDP) configured to display an image, 2) a chassis base having first and second surfaces opposing each other, wherein the first surface of the chassis base supports the PDP and 3) a printed circuit board assembly (PBA) formed on the second surface of the chassis base. The PBA includes i) a plurality of electrode pads formed on a surface of the PBA and ii) a plurality of dummy pads interposed between and not electrically connected to neighboring electrode pads. The device further includes a flexible printed circuit (FPC) configured to electrically connect the PBA and the PDP, wherein the surface of the PBA faces the FPC, wherein the FPC contacts i) at least one of the dummy pads and ii) the electrode pads, and wherein the least one dummy pad and the electrode pads have substantially the same height defined from the surface of the PBA to the FPC.

### RELATED APPLICATIONS

This application claims priority to and the benefit of Korean Patent Application No. 10-2009-0071785 filed in the Korean Intellectual Property Office on Aug. 4, 2009, the entire contents of which are incorporated herein by reference.

### BACKGROUND

1. Field

The described technology generally relates to a plasma display device, and more particularly it relates to a plasma display device that prevents a bonding defect between an electrode pad and a flexible printed circuit (FPC) of a printed circuit board assembly (PBA).

2. Description of the Related Technology

A plasma display device includes a plasma display panel (PDP), a chassis base for supporting the PDP, and a plurality of printed circuit board assemblies (PBAs) mounted on the chassis base.

The PDP displays an image using red (R), green (G), and blue (B) visible light created by exciting phosphors using vacuum ultraviolet (VUV) radiation emitted from plasma generated by a gas discharge.

### SUMMARY OF CERTAIN INVENTIVE ASPECTS

One aspect is a plasma display device having an advantage of preventing a bonding defect between an electrode pad and a flexible printed circuit (FPC) of a printed circuit board assembly (PBA).

Another aspect is a plasma display device which includes: a plasma display panel (PDP) realizing an image; a chassis base supporting the PDP at one side; a printed circuit board assembly (PBA) mounted on one side of the chassis base from an opposite side of the PDP; and a flexible printed circuit (FPC) electrically connecting the PBA and the PDP. The PBA includes a plurality of electrode pad groups provided along a first direction in one side of the PBA and dummy pads formed as a group between two neighboring electrode pad groups among the plurality of electrode pads. A plurality of electrode pads arranged in the electrode pad group protruding from the one side of the PBA so as to be bonded to the FPC through thermal compression and extending in a second direction that crosses the first direction, and the electrode pad and the dummy pad have the same height at one side of the PBA.

The electrode pad group includes a first electrode pad group arranged at an end portion of the one side of the PBA and a second electrode pad group separated from the first electrode pad group along the second direction and arranged closer to the center of the PBA than the first electrode pad group.

The electrode pads include a plurality of first pads arranged in the first electrode pad group and a plurality of second electrode pads arranged in the second electrode pad group and the first and second electrode pads respectively have center lines set to the second direction from the center of the first direction. The center lines of the first electrode pads and the center lines of the second electrode pads may be alternately arranged along the first direction.

The dummy pads are respectively formed as stripes along the second direction, and may correspond to the first and second electrode pads toward the first direction.

The electrode pads include a plurality of first electrode pads arranged in the first electrode pad group and a plurality of second electrode pads arranged in the second electrode pad group, and, in a plane set to the first and second directions, a plane center of each of the first electrode pad, the second electrode pad, and the dummy pad may form a triangle.

The electrode pads include a plurality of first electrode pads arranged in the first electrode pad group and a plurality of second electrode pads arranged in the second electrode pad group, the first electrode pad and the dummy pad that are closest to each other in the first direction may have a first distance therebetween, the second electrode pad and the dummy pad that are closest to each other in the first direction may have a second distance therebetween, and the first distance and the second distance may be different from each other.

The electrode pads include a plurality of first electrode pads arranged in the first electrode pad group and a plurality of second electrode pads arranged in the second electrode pad group, and the first electrode pad, the second electrode pad, and the dummy pad may the same height at one side of the PBA.

The dummy pad and the electrode pad may have the same width in the first direction.

The dummy pads face the first and second electrode pads along the first direction, and may be formed of a plurality of dots separately arranged along the second direction. At least one side of each dot may be formed as an arc.

The dummy pads may be respectively formed as stripes along an oblique direction that crosses the first or second direction.

The dummy pads face the first and second electrode pads along an oblique direction that crosses the first or second direction, and may be respectively formed as a plurality of dots separately arranged along the oblique direction. At least one side of each dot may be formed as an arc.

Another aspect is a plasma display device comprising: a plasma display panel (PDP) configured to display an image; a chassis base having first and second surfaces opposing each other, wherein the first surface of the chassis base supports the PDP; a printed circuit board assembly (PBA) mounted on the second surface of the chassis base; and a flexible printed circuit (FPC) configured to electrically connect the PBA and the PDP, wherein the PBA comprises i) a plurality of electrode pad groups provided along a first direction on a surface of the PBA and ii) a plurality of dummy pads interposed between two neighboring electrode pad groups, wherein the surface of the PBA faces the FPC, wherein a plurality of electrode pads arranged in each of the electrode pad groups extend in a second direction that crosses the first direction and protrude from the surface of the PBA so as to be bonded to the FPC through thermal compression, and wherein the electrode pads and the dummy pads have substantially the same height defined from the surface of the PBA toward the FPC.

In the above device, each of the electrode pad groups comprises: a first electrode pad group arranged at an end portion of the surface of the PBA; and a second electrode pad group separated from the first electrode pad group along the second direction and arranged closer to the center of the PBA than the first electrode pad group.

In the above device, the first electrode pad group comprises a plurality of first electrode pads, wherein the second electrode pad group comprises a plurality of second electrode pads, wherein each of the first electrode pads has a first center line which passes through the center thereof along the second direction, wherein each of the second electrode pads has a second center line which passes through the center thereof and is substantially parallel with the first center line, wherein the first center lines and the second center lines are alternately arranged along the first direction.

In the above device, the dummy pads are formed in a stripe pattern along the second direction, and wherein the dummy pads are substantially aligned with adjacent electrode pad groups along the second direction. In the above device, each of the first electrode pads has a first length, wherein each of the second electrode pads has a second length, wherein each of the dummy pads has a third length, wherein a gap, formed between the first electrode pad and the corresponding second electrode pad, has a fourth length, wherein the first to fourth lengths are defined along the first direction, and wherein the third length is substantially the same as the combination of the first, second and fourth lengths. In the above device, the first electrode pad group comprises a plurality of first electrode pads, wherein the second electrode pad group comprises a plurality of second electrode pads, wherein each of the first electrode pads has a first center, wherein each of the second electrode pads has a second center, wherein each of the dummy pads has a third center, and wherein the first, second and third centers are arranged to substantially form a triangle.

In the above device, the first electrode pad group comprises a plurality of first electrode pads, wherein the second electrode pad group comprises a plurality of second electrode pads, wherein the first electrode pad and the dummy pad that are closest to each other in the first direction have a first distance therebetween, wherein the second electrode pad and the dummy pad that are closest to each other in the first direction have a second distance therebetween, and wherein the first distance and the second distance are different from each other. In the above device, the first electrode pad group comprises a plurality of first electrode pads, wherein the second electrode pad group comprises a plurality of second electrode pads, wherein each of the first and second electrode pads and each of the dummy pads have substantially the same height defined from the surface of the PBA toward the FPC.

In the above device, each of the dummy pads and each of the electrode pads have substantially the same width in the first direction. In the above device, the dummy pads comprise a plurality of dots separately and substantially evenly arranged along the second direction. In the above device, at least one side of each dot is non-linear. In the above device; the dummy pads are formed in a stripe pattern along an oblique direction that crosses the first or second direction. In the above device, the dummy pads comprise a plurality of dots separately and substantially evenly arranged along the oblique direction. In the above device, at least one side of each dot is non-linear.

Another aspect is a plasma display device comprising: a plasma display panel (PDP) configured to display an image; a chassis base having first and second surfaces opposing each other, wherein the first surface of the chassis base supports the PDP; a printed circuit board assembly (PBA) formed on the second surface of the chassis base, wherein the PBA comprises i) a plurality of electrode pads formed on a surface of the PBA and ii) a plurality of dummy pads interposed between and not electrically connected to neighboring electrode pads; and a flexible printed circuit (FPC) configured to electrically connect the PBA and the PDP, wherein the surface of the PBA faces the FPC, wherein the FPC contacts i) at least one of the dummy pads and ii) the electrode pads, and wherein the least one dummy pad and the electrode pads have substantially the same height defined from the surface of the PBA to the FPC.

In the above device, all of the dummy pads and all of the electrode pads have substantially the same height defined from the surface of the PBA to the FPC, and wherein the FPC contacts more than one of the dummy pads. In the above device, the dummy pads comprise a plurality of dots separately and substantially evenly arranged on the surface of the PBA. In the above device, the dummy pads are formed in a stripe pattern and slanted with respect to the electrode pads.

Another aspect is a printed circuit board assembly (PBA) for a plasma display device (PDP), the PBA comprising: a plurality of electrode pads to be connected to a flexible printed circuit (FPC) which is configured to electrically connect the PBA and the PDP; and a plurality of dummy pads interposed between the plurality of electrode pads and not electrically connected to neighboring electrode pads, wherein at least one of the dummy pads and the electrode pads have substantially the same height defined from the PBA to the FPC.

### BRIEF DESCRIPTION OF THE DRAWINGS

FIG. 1 is a schematic perspective view of a plasma display device according to a first exemplary embodiment of the present invention.

FIG. 2 is a cross-sectional view of FIG. 1, taken along the line II-II.

FIG. 3 is a top plan view of an address buffer board assembly representing neighboring electrode pad groups and dummy pads.

FIG. 4 is an exploded perspective view of the address buffer board assembly and a flexible printed circuit (FPC).

FIG. 5 is a partial top plan view of an address buffer board assembly representing neighboring electrode pad groups and dummy pads according to a second exemplary embodiment of the present invention.

FIG. 6 is a partial top plan view of an address buffer board assembly representing neighboring electrode pad groups and dummy pads according to a third exemplary embodiment of the present invention.

FIG. 7 is a partial top plan view of an address buffer board assembly representing neighboring electrode pad groups and dummy pads according to a fourth exemplary embodiment of the present invention.

### DETAILED DESCRIPTION OF CERTAIN INVENTIVE EMBODIMENTS

Among the PBAs, an address buffer board assembly is mounted on the chassis base at an opposite side of the PDP to control address electrodes provided in the PDP, and is connected to the address electrodes through a flexible printed circuit (FPC).

The FPC includes a driver integrated circuit (IC) to form a driver IC package, and may form a tape carrier package (TCP). One end of the FPC is attached to the address electrodes and the other end is connected to the address buffer board assembly.

A plurality of FPCs may be connected to the address buffer board assembly by interposing a connector therebetween or may be bonded to the address buffer board through thermal compression. The address buffer board assembly includes a plurality of electrode pad groups each of which protrudes with a height so as to be connected to each FPC.

Since neighboring electrode pad groups are spaced apart, which forms a gap therebetween, when the FPC is bonded to the electrode pad group through thermal compression, a bonding plane is not even or flat due to the gap. This non-planar bonding surface causes a bonding defect between the electrode pads and the FPC.

Embodiments of the present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. The drawings and description are to be regarded as illustrative in nature and not restrictive. Like reference numerals designate like elements throughout the specification.

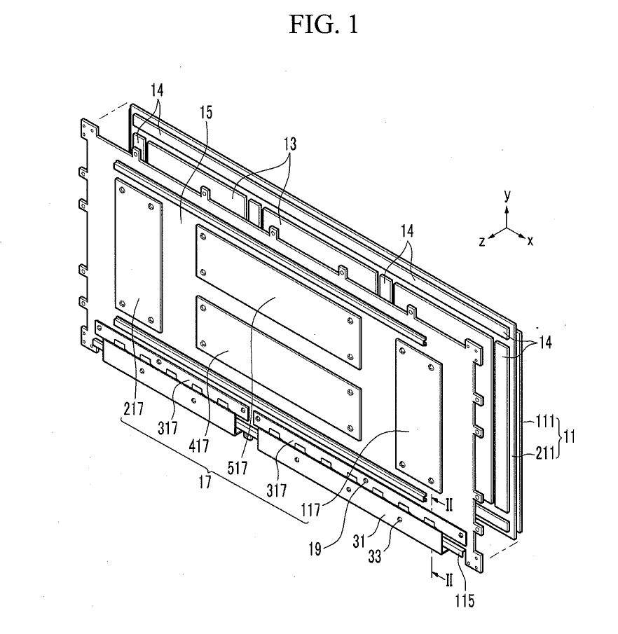

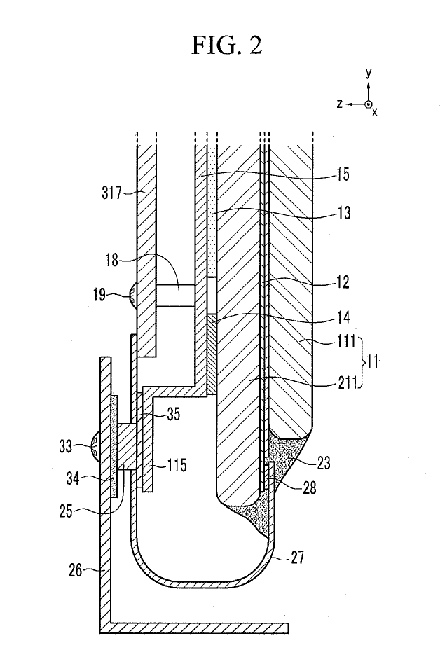

FIG. 1 is a schematic perspective view of a plasma display device according to a first exemplary embodiment of the present invention, and FIG. 2 is a cross-sectional view of FIG. 1, taken along the line II-II.

Referring to FIG. 1 and FIG. 2, a plasma display device includes a plasma display panel (PDP) 11 that displays an image on a front surface by using gas discharge, heat dissipation sheets 13, a chassis base 15, and printed circuit board assemblies (PBAs) 17.

The chassis base 15 is attached to a rear surface of the PDP 11 by a double-sided adhesive tape 14, interposing the heat dissipation sheets 13 therebetween to support the PDP 11.

The PBAs 17 are mounted on a rear surface of the chassis base 15. For example, the PBAs 17 are placed on a plurality of bosses 18 provided in the chassis base 15 and fastened to the bosses 18 by setscrews 19 fastened thereto.

In addition, the PBAs 17 configured to drive the PDP 11 are connected to the PDP 11 through flexible printed circuits (FPCs) 27.

The PDP 11 includes electrodes, for example, sustain and scan electrodes (not shown) and an address electrode 12, for generating gas discharge in a discharge cell (not shown). Therefore, the plurality of PBAs 17 are provided to respectively perform functions for driving the electrodes of the PDP 11.

For example, the PBAs 17 include a sustain board assembly 117 controlling the sustain electrode (not shown), a scan board assembly 217 controlling the scan electrode (not shown), and an address buffer board 317 controlling the address electrode 12. In one embodiment, the sustain board assembly 117 and the scan board assembly 217 are connected to the sustain and scan electrodes, respectively, through a respective FPC (not shown). The address buffer board assembly 317 is connected to the address electrode 12 through the FPC 27.

In addition, the PBAs 17 further include an image processing/controlling board assembly 417 that externally receives a video signal, generates control signals respectively for driving the sustain and scan electrodes, and applies the control signals to the corresponding board assemblies. The PBAs 17 also include a power board assembly 517 that supplies power for driving each of the board assemblies.

One embodiment of the present invention is applied to a structure for electrically connecting the PBAs 17 and the FPCs 27. Another embodiment may be applied to i) a connection structure of the sustain board assembly 117 and the FPC (not shown), ii) a connection structure of the scan board assembly 217 and the FPC (not shown), and iii) a connection structure of the address buffer board assembly 317 and the FPC 27.

For convenience, the connection structure of the address buffer board assembly 317 and the FPC 27 will be exemplarily described in the present exemplary embodiment. The FPC 27 is connected to the address buffer board assembly 317 while surrounding one side of the chassis base 15. In one embodiment, the FPC 27 is bonded to the address buffer board assembly 317 through thermal compression.

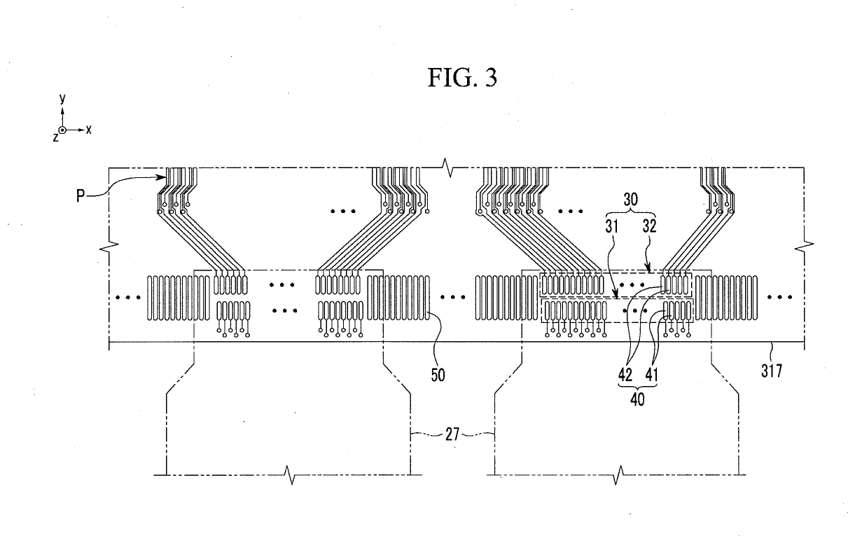

FIG. 3 is a partial top plan view of an address buffer board assembly representing neighboring electrode pad groups and dummy pads according to one embodiment. Referring to FIG. 3, the address buffer board assembly 317 includes electrode pad groups 30 and dummy pads 50 that are alternately arranged along a first direction (x-axis direction). That is, the dummy pads 50 are respectively disposed at both sides of the electrode pad group in the x-axis direction, and the electrode pad groups 30 are respectively disposed at both sides of the dummy pads 50 in the x-axis direction.

Each of the electrode pad groups 30 includes a group of electrode pads 40, and the dummy pads 50 are formed as a group. The electrode pads 40 are electrically connected to the address buffer board assembly 317 through a circuit pattern P, and the dummy pads 50 are electrically separated from the circuit pattern P.

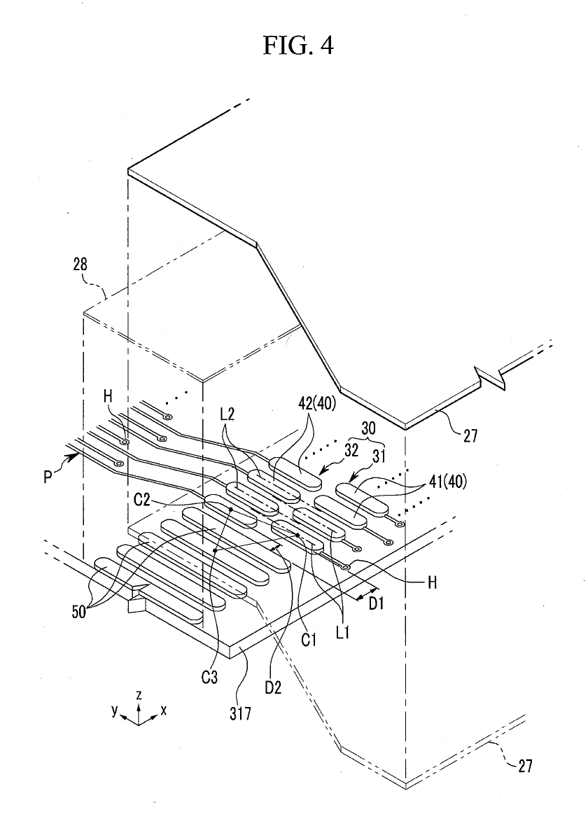

FIG. 4 is an exploded perspective view of the address buffer board assembly and the FPC. In one embodiment, the electrode pads 40 protrude from one side of the address buffer board assembly 317 and extend in a second direction (y-axis direction), and are bonded to the FPC 27 through thermal compression. That is, the electrode pads 40 are electrically connected to terminals (not shown) of the FPC 27.

An anisotropic conductive film (ACF) 28 is provided between the electrode pads 40 of the address buffer board assembly 317 and the FPC 27. During the thermal compression process, the ACF 28 forms a current path through micro-conductive balls (not shown) between the electrode pads 40 and the FPC 27.

Each electrode pad group 30 including a plurality of electrode pads 40 includes a first electrode pad group 31 and a second electrode pad group 32. The first and second electrode pad groups 31 and 32 are disposed at a distance from each other along the y-axis direction on the surface of one side of the address buffer board assembly 317.

That is, the first electrode pad group 31 is arranged at an end portion on the surface of one side of the address buffer board assembly 317, and the second electrode pad group 32 is arranged closer to the center of the address buffer board assembly 317 than the first electrode pad group 31.

In addition, the first electrode pad group 31 includes a plurality of first electrode pads 41 and the second electrode pad group 32 includes a plurality of second electrode pads 42. In one embodiment, as shown in FIG. 4, the second electrode pads 42 close to the center are directly connected to the circuit pattern P, and the first electrode pads 42 at the end portion are connected to the circuit pattern P through a via hole H.

Since the electrode pad group 30 is divided into the first and second electrode pad groups 31 and 32 along the Y-axis direction, more electrode pads 40 may be provided on the surface of the address buffer board assembly 317. As stated, two electrode pads 40, for example, first and second electrode pads 41 and 42, are formed along one y-axis direction.

In one embodiment, as an allowable area along a length direction (e.g., Y-axis direction) of the electrode pads 40 is increased in the PBA 17, more electrode pads (e.g., three or more) may be formed in the allowable area.

In one embodiment, the first electrode pads 41 and the second electrode pads 42 respectively have first and second center lines L1 and L2 defined along the y-axis direction, and have substantially the same line widths along the x-axis direction.

In one embodiment, the first and second center lines L1 and L2 of each of the first and second electrode pads 41 and 42 are alternately arranged along the x-axis direction. Due to this, the number of electrode pads 40 having a constant line width is increased within a limited width range, and the structure of the circuit pattern P is simplified.

In one embodiment, the circuit pattern P includes lines alternately connected to the first and second electrode pads 41 and 42, and some of the lines are directly connected to the second electrode pads 42. In addition, lines connected to the first electrode pads 41 are formed correspondingly between second electrode pads 42 on a surface of an opposite side of the first electrode pad 41 in the address buffer board assembly 317. These lines are connected to a via hole H formed, for example, in an edge of the address buffer board assembly 317, as shown in FIG. 4.

In one embodiment, with respect to the x-y plane on the surface of one side of the address buffer board assembly 317, the first electrode pad 41, the second electrode pad 42, and the dummy pad 50 respectively have plane centers C1, C2, and C3 that form substantially a triangle. This is because the first and second center lines L1 and L2 of the first and second electrode pads 41 and 42 are alternately arranged along the x-axis direction.

In one embodiment, the dummy pad 50 is formed integrally (e.g., as a single unit) along the y-axis direction. The dummy pad 50 may be substantially aligned with the first and second electrode pad groups 31 and 32 along the x-axis direction. The dummy pad 50 may be integrally formed, that is, formed in a strip pattern along the y-axis direction.

In one embodiment, the plurality of dummy pads 50 are provided between the electrode pads 40 that neighbor along the x-axis direction (See FIG. 3). In one embodiment, the first and second electrode pads 41 and 42 and the dummy pad 50 protrude from the surface of one side of the address buffer board assembly 317 and have substantially the same heights. These dummy pads 50 significantly reduce an empty area (gap) between the address buffer board assembly 317 and the FPC 27 compared to a comparative example where no dummy pads 50 are interposed between the electrode pad groups 30 (i.e., large empty area). Thus, the dummy pads 50 provide a substantially planar bonding surface between the electrode pad groups 30 and FPC 27. Therefore, the planarity of the bonding surface can be significantly improved, since the electrode pad groups 30 and the FPC 27 can significantly more tightly be bonded to each other.

In the x-axis direction, the outermost dummy pad 50 among the dummy pads 50 is disposed at a distance from the outmost electrode pad 40 among the electrode pads 40. In this case, a first electrode pad 41 of the outermost electrode pad 40 is separated by a first distance D1 from the outermost dummy pad 50 and a second electrode pad 42 of the outermost electrode pad 40 is separated by a second distance D2 from the outermost dummy pad 50. In addition, the first and second distances D1 and D2 are different from each other. In one embodiment, D1 is greater than D2. In another embodiment, D2 is greater than D1.

The FPC 27 is bonded to a surface of one side of the address buffer board assembly 317 where the electrode pad group 30 and the dummy pad 50 are formed along the x-axis direction through thermal compression, interposing the ACF 28 therebetween.

In this case, the dummy pad 50 provided between adjacent electrode pad groups 30 forms a bonding plane having substantially the same planarity with the electrode pad groups 30 to thereby support the thermally compressed FPC 27. Therefore, bonding defects of the FPC 27 due to planarity defects around the electrode pad groups 30 can be prevented.

In addition, as shown in FIG. 3 and FIG. 4, the dummy pads 50 are formed as a stripe pattern in a space formed between the electrode pad groups 30. Therefore, the dummy pads 50 eliminate bubbles by forming an air path through the dummy pads 50 while forming the bonding plane of which the height is substantially equal to that of the electrode pad groups 30 so that the bonding defects of the FPC 27 can be further prevented without interrupting adhesion of the ACF 28.

Referring back to FIG. 2, the FPC 27 is connected to the address electrode 12 of the PDP 11, and a sealing agent 23 seals both sides of the FPC 27 at side ends of a front substrate 111 and a rear substrate 211.

The FPC 27 includes a driver integrated circuit (IC) 25 that generates a control signal to be applied to the address electrode 12, and is formed, for example, as a tape carrier package (TCP).

The FPC 27 surrounds a bent portion 115 of the chassis base 15 while connecting the address electrode 12 and the address buffer board assembly 317, and the driver IC 25 mounted on the FPC 27 is disposed in the bent portion 115.

A cover plate 26 is fastened to the bent portion 115 by a setscrew 33 to cover the driver IC 25 for protection. In this case, thermal grease 35 is interposed between the driver IC 25 and the bent portion 115, and a heat dissipation sheet 34 is interposed between the cover plate 26 and the driver IC 25 for respectively protecting the driver integrated circuit 25 from, for example, external impact and for heat dissipation.

Hereinafter, various exemplary embodiments of the present invention will be described, and descriptions of parts having been described in the first exemplary embodiment will be omitted.

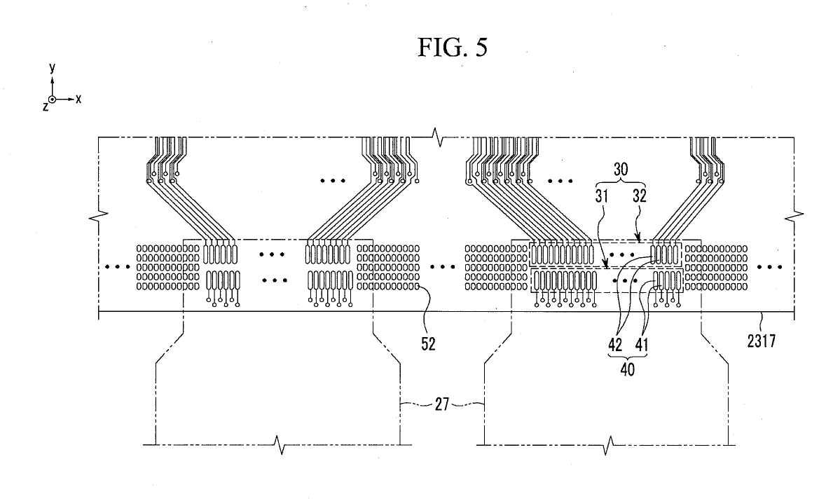

FIG. 5 is a partial top plan view of an address buffer board assembly 2317 representing neighboring electrode pad groups and dummy pads according to a second exemplary embodiment of the present invention. According to the second exemplary embodiment, dummy pads 52 are formed by a plurality of dots separately arranged along the y-axis direction, while facing a first electrode pad 41 and a second electrode pad 42 along the x-axis direction. The dots may be substantially evenly spaced apart from each other.

The dummy pads 52 formed of the plurality of dots eliminate bubbles by forming an air path along the x-axis and y-axis directions between the dummy pads 52 while forming a bonding plane having substantially the same height as the electrode pad groups 30, and therefore a bonding defect of the FPC 27 can be further efficiently prevented without interrupting adhesion of the ACF 28. The dots forming the dummy pads 52 are formed in a substantially circular or oval shape having an arc at least at one side when viewed from the x-y plane, and therefore the air path may be more smoothly formed during a bonding process. At least one side of the dots may be non-linear.

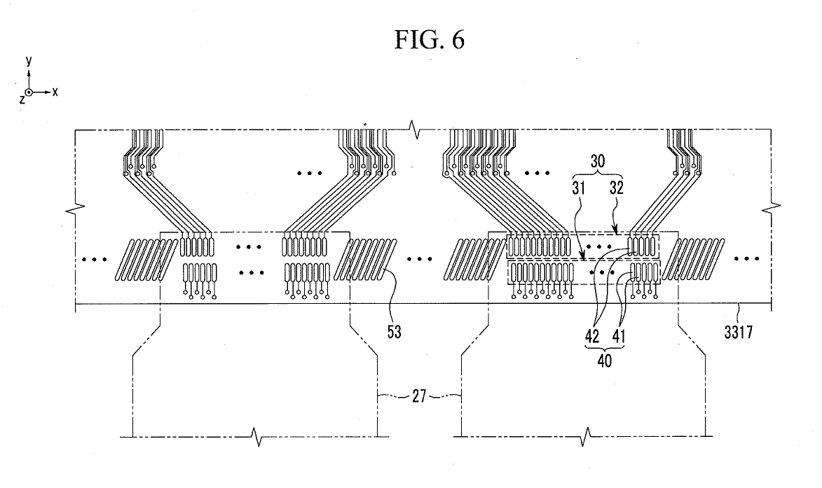

FIG. 6 is a top plan view of an address buffer board assembly 3317 representing neighboring electrode pad groups and dummy pads according to a third exemplary embodiment of the present invention. According to the third exemplary embodiment, dummy pads 53 are respectively formed as strips along an oblique line that crosses the x-axis direction or the y-axis direction. The dummy pads 53 eliminate bubbles by forming an air path in an oblique direction between the dummy pads 53 while forming a bonding plane with a height that is substantially the same as those of the electrode pad groups 30, and therefore a bonding defect of the FPC 27 can be further prevented without interrupting adhesion of the ACF 28.

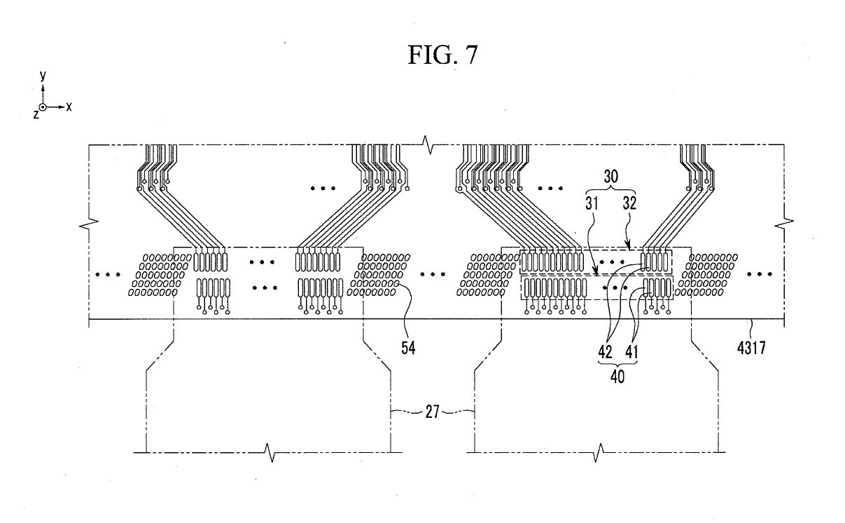

FIG. 7 is a partial top plan view of an address buffer board assembly 4317 representing neighboring electrode pad groups and dummy pads according to a fourth exemplary embodiment of the present invention. According to the fourth exemplary embodiment, dummy pads 54 are formed by a plurality of dots separately arranged along an oblique direction that crosses the x-axis direction or the y-axis direction, while facing a first electrode pad 41 and a second electrode pad 42 along the oblique direction.

The dummy pads 54 formed by the plurality of dots eliminate bubbles by forming an air path in the oblique direction between the dummy pads 54 while forming a bonding plane having the same height as the electrode pad groups 30, and therefore a bonding defect of the FPC 27 can be further efficiently prevented without interrupting adhesion of the ACF 28. When viewed from the x-y plane, at least one side of each of the dots forming the dummy pads 54 has an arc or oval shape so that the air path can be more smoothly formed during a bonding process.

According to at least one embodiment, dummy pads are provided between electrode pad groups of the PBA so that the FPC can be more tightly and securely bonded to the electrode pads through thermal compression.

Since the planarity of the bonding surface is significantly enhanced, the bonding defect of the electrode pads and the FPC is prevented.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A plasma display device comprising:
a plasma display panel (PDP) configured to display an image;
a chassis base having first and second surfaces opposing each other, wherein the first surface of the chassis base supports the PDP;
a printed circuit board assembly (PBA) mounted on the second surface of the chassis base; and
a flexible printed circuit (FPC) configured to electrically connect the PBA and the PDP,
wherein the PBA comprises i) a plurality of electrode pad groups provided along a first direction on a surface of the PBA and ii) a plurality of dummy pads interposed between two neighboring electrode pad groups, wherein the surface of the PBA faces the FPC, wherein a plurality of electrode pads arranged in each of the electrode pad groups extend in a second direction that crosses the first direction and protrude from the surface of the PBA so as to be bonded to the FPC through thermal compression, and wherein the electrode pads and the dummy pads have substantially the same height defined from the surface of the PBA toward the FPC.

2. The plasma display device of claim 1, wherein each of the electrode pad groups comprises:
a first electrode pad group arranged at an end portion of the surface of the PBA; and
a second electrode pad group separated from the first electrode pad group along the second direction and arranged closer to the center of the PBA than the first electrode pad group.

3. The plasma display device of claim 2, wherein the first electrode pad group comprises a plurality of first electrode pads, wherein the second electrode pad group comprises a plurality of second electrode pads, wherein each of the first electrode pads has a first center line which passes through the center thereof along the second direction, wherein each of the second electrode pads has a second center line which passes through the center thereof and is substantially parallel with the first center line, wherein the first center lines and the second center lines are alternately arranged along the first direction.

4. The plasma display device of claim 2, wherein the dummy pads are formed in a stripe pattern along the second direction, and wherein the dummy pads are substantially aligned with adjacent electrode pad groups along the second direction.

5. The plasma display device of claim 4, wherein each of the first electrode pads has a first length, wherein each of the second electrode pads has a second length, wherein each of the dummy pads has a third length, wherein a gap, formed between the first electrode pad and the corresponding second electrode pad, has a fourth length, wherein the first to fourth lengths are defined along the first direction, and wherein the third length is substantially the same as the combination of the first, second and fourth lengths.

6. The plasma display device of claim 2, wherein the first electrode pad group comprises a plurality of first electrode pads, wherein the second electrode pad group comprises a plurality of second electrode pads, wherein each of the first electrode pads has a first center, wherein each of the second electrode pads has a second center, wherein each of the dummy pads has a third center, and wherein the first, second and third centers are arranged to substantially form a triangle.

7. The plasma display device of claim 2, wherein the first electrode pad group comprises a plurality of first electrode pads, wherein the second electrode pad group comprises a plurality of second electrode pads, wherein the first electrode pad and the dummy pad that are closest to each other in the first direction have a first distance therebetween, wherein the second electrode pad and the dummy pad that are closest to each other in the first direction have a second distance therebetween, and wherein the first distance and the second distance are different from each other.

8. The plasma display device of claim 2, wherein the first electrode pad group comprises a plurality of first electrode pads, wherein the second electrode pad group comprises a plurality of second electrode pads, wherein each of the first and second electrode pads and each of the dummy pads have substantially the same height defined from the surface of the PBA toward the FPC.

9. The plasma display device of claim 1, wherein each of the dummy pads and each of the electrode pads have substantially the same width in the first direction.

10. The plasma display device of claim 1, wherein the dummy pads comprise a plurality of dots separately and substantially evenly arranged along the second direction.

11. The plasma display device of claim 10, wherein at least one side of each dot is non-linear.

12. The plasma display device of claim 1, wherein the dummy pads are formed in a stripe pattern along an oblique direction that crosses the first or second direction.

13. The plasma display device of claim 12, wherein the dummy pads comprise a plurality of dots separately and substantially evenly arranged along the oblique direction.

14. The plasma display device of claim 13, wherein at least one side of each dot is non-linear.

15. A plasma display device comprising:
a plasma display panel (PDP) configured to display an image;
a chassis base having first and second surfaces opposing each other, wherein the first surface of the chassis base supports the PDP;
a printed circuit board assembly (PBA) formed on the second surface of the chassis base, wherein the PBA comprises i) a plurality of electrode pads formed on a surface of the PBA and ii) a plurality of dummy pads interposed between and not electrically connected to neighboring electrode pads; and
a flexible printed circuit (FPC) configured to electrically connect the PBA and the PDP,
wherein the surface of the PBA faces the FPC, wherein the FPC contacts i) at least one of the dummy pads and ii) the electrode pads, and wherein the least one dummy pad and the electrode pads have substantially the same height defined from the surface of the PBA to the FPC.

16. The plasma display device of claim 15, wherein all of the dummy pads and all of the electrode pads have substantially the same height defined from the surface of the PBA to the FPC, and wherein the FPC contacts more than one of the dummy pads.

17. The plasma display device of claim 15, wherein the dummy pads comprise a plurality of dots separately and substantially evenly arranged on the surface of the PBA.

18. The plasma display device of claim 17, wherein the dummy pads are formed in a stripe pattern and slanted with respect to the electrode pads.

19. A printed circuit board assembly (PBA) for a plasma display device (PDP), the PBA comprising:
a plurality of electrode pads to be connected to a flexible printed circuit (FPC) which is configured to electrically connect the PBA and the PDP; and
a plurality of dummy pads interposed between the plurality of electrode pads and not electrically connected to neighboring electrode pads,
wherein at least one of the dummy pads and the electrode pads have substantially the same height defined from the PBA to the FPC.
